(19) United States
(12) Patent Application Publication
(10) Pub. No.: US 2009/0146225 A1
(43) Pub. Date: Jun. 11, 2009

(54) SEMICONDUCTOR DEVICE AND METHOD FOR FABRICATING THE SAME

(76) Inventor: Doo-Sung Lee, Taebaek-si (KR)

Correspondence Address: SHERR & VAUGHN, PLLC, 620 HERNDON PARKWAY, SUITE 200, HERNDON, VA, 20170, US

(21) Appl. No.: 12/330,670

(22) Filed: Dec. 9, 2008

(30) Foreign Application Priority Data
Dec. 10, 2007 (KR) 10-2007-0127511

(51) Int. Cl. H01L 21/28; H01L 29/49

(52) U.S. Cl. 257/413; 438/592; 257/E29.156; 257/E21.199

(57) ABSTRACT

A method for manufacturing a semiconductor device includes a gate dielectric film formed over an active area of a semiconductor substrate, and a gate electrode formed over the gate dielectric film and formed of a silicidation film having a polysilicon area at the bottom of the gate electrode. Therefore, with embodiments, a work function can variously controlled and the gate pattern having different work function can be applied to the transistors by using a non-silicided polysilicon region due to the formation a partially silicided gate pattern, such that the resistance of the gate electrode and junction can be reduced, making it possible to maximize the device characteristics.

The present application claims priority under 35 U.S.C. 119 to Korean Patent Application No. 10-2007-0127511 (filed on Dec. 10, 2007), which is hereby incorporated by reference in its entirety.

### BACKGROUND

With the rapid development in the information and communication fields, and the popularization of information media such as computers, semiconductor devices have also been rapidly developed. In accordance with higher integration of semiconductor devices to achieve higher functionality, various methods have been studied and developed to reduce the feature size of individual devices formed on a substrate, and to maximize the performance of semiconductor devices. Accordingly, the miniaturization of semiconductor devices has progressed in proportion with methods for fabricating highly integrated semiconductor devices.

A polysilicon gate of a semiconductor device causes various problems such as high gate resistance, polysilicon depletion, boron penetration and the like in accordance with the reductions in size of the semiconductor device. Therefore, the polysilicon gate has been replaced by a metal gate or the like. However, in the cases of metal gates using pure TiN, TaN, TiSiN and the like, a work function of an NMOS or a PMOS is rarely changed. This creates a problem in that the properties of the device are deteriorated when the metal gate is applied to a semiconductor device which requires different work functions for the respective transistors.

### SUMMARY

Embodiments relate to a semiconductor device which may have a gate pattern that is partially silicided, and a method for fabricating the same. Embodiments relate to a semiconductor device which includes: a semiconductor substrate having at least one active area. A gate dielectric film may be formed over an active area of the semiconductor substrate. A gate electrode may be disposed over the gate dielectric film, the gate electrode formed of a silicidation film over a polysilicon area.

Embodiments relate to a method for fabricating a semiconductor device that may include at least one of the following: forming a gate dielectric film over a semiconductor substrate, forming a polysilicon film over the gate dielectric film, forming a metal film over the polysilicon film, and forming a silicidation film by reacting the metal film with a portion of the polysilicon film.

Embodiments relate to an apparatus that may include at least one of the following: a semiconductor substrate having at least one active area; a gate dielectric film formed over an active area of the semiconductor substrate; and a gate electrode formed over the gate dielectric film, the gate electrode formed of a silicidation film over a polysilicon area.

Embodiments relate to a method that may include at least one of the following: forming a gate dielectric film over a semiconductor substrate; and then forming a polysilicon film over the gate dielectric film; and then forming a metal film over the polysilicon film; and then forming a silicidation film by reacting the metal film with a portion of the polysilicon film.

Embodiments relate to a method for fabricating a semiconductor device that may include at least one of the following:

### DRAWINGS

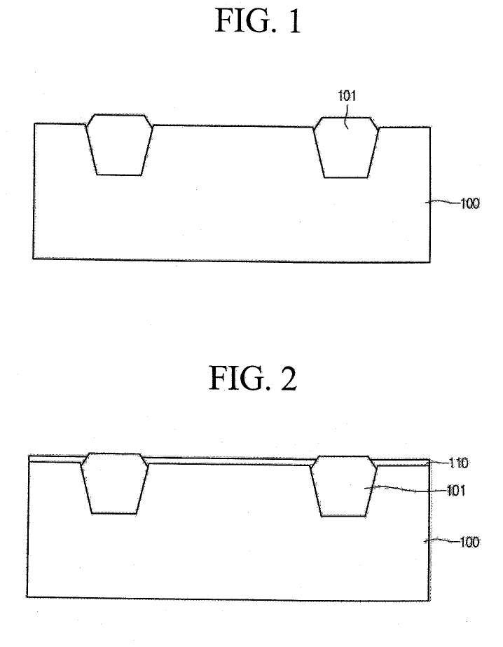

Example FIGS. 1 to 6 are cross-sectional views showing processes of a method for fabricating a semiconductor device according to embodiments.

### DESCRIPTION

Example FIGS. 1 to 6 are cross-sectional views showing processes of a method for fabricating a semiconductor device according to embodiments.

As shown in example FIG. 1, a device isolation film pattern 101 may be formed in a semiconductor substrate 100, as follows. The device isolation pattern 101 may be used for defining an active area where a device may be formed on the semiconductor substrate 100. First, a hard mask may be formed over the semiconductor substrate 100. The semiconductor substrate 100 may be etched at a predetermined depth using the hard mark to form a trench. The trench may be formed to surround the active area. A trench filling material may be thickly deposited over the whole the semiconductor substrate 100, burying the trench. An oxide film may be used as the trench filling material. The oxide film may be deposited using an atmospheric pressure chemical vapor deposition (APCVD) method. For example, a material such as O₃-TEOS (tetraetylorthosilicate) may be used as the trench filling material. Thereafter, a chemical mechanical polishing (CMP) may be performed so that the oxide film remains only in the trench, thereby forming the device isolation pattern 101.

As shown in example FIG. 2, a gate oxide film 110 may be formed over the entire semiconductor substrate 100, in which the device isolation pattern 101 is formed, as a gate dielectric film. The gate oxide film 110 may be formed using a thermal oxidation method or the like. For example, the gate oxide film 110 may be deposited over the semiconductor substrate 100 under an oxygen atmosphere at a temperature of 700° C. to 900° C. using a furnace thermal process (FTP) method. The gate oxide film 110 may be formed with a thickness of 10 Å to 100 Å. A nitride plasma treatment may also be performed over the gate oxide film 110, according to embodiments. In this case, the gate oxide film 110 becomes a gate oxynitride film 110. Here, the gate oxynitride film 110 maintains an effective oxide thickness (EOT) but increases a physical thickness, making it possible to secure process margins and device characteristics.

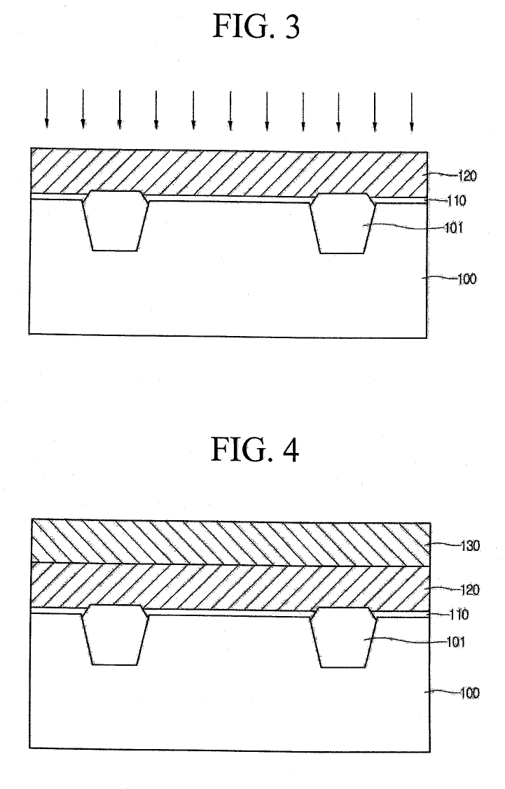

As shown in example FIG. 3, a polysilicon film 120 may be formed over the semiconductor substrate 100 over which the gate oxynitride film 110 is formed. The polysilicon film 120 may be formed with a thickness of about 500 Å to 2000 Å, at a temperature of about 500° C. to 550° C., and at a pressure of about 0.1 to 3 torr, by a low-power chemical vapor deposition (LP-CVD) method using a Si source gas, such as SiH₄ or SiH₆, and PH₃ gas. The work function can be controlled by ion-implanting an n type impurity or a p type impurity into the polysilicon film 120. The n type impurity may include B, BF₂ and the like, and the p type impurity may include P, As and the like.

Next, as shown in example FIG. 4, a metal film 130 may be formed over the polysilicon film 120. The metal film 130, which is a metal film for forming silicide, may include at least one selected from a group including of Ni, Co, Ti, Ta, W and Pt. The metal film 130 may be deposited by a physical vapor deposition (PVD) method. The metal film 130 may be formed at a thickness of 100 Å to 2000 Å. When the metal film 130 is an Ni film, for example, the metal film 130 may be formed at a thickness of 200 Å to 1000 Å. The Ni film and polysilicon film 120 form a silicidation film of NiSi, and the reaction ratio of the Ni film and polysilicon film 120 may be 1:1.7 to 1:2.7. For example, the reaction ratio may be 1:2.1. When the metal film 130 is a Co film, for example, the metal film 130 may be formed at a thickness of 400 Å to 800 Å. The Co film and polysilicon film 120 form a silicidation film of CoSi₂, and the reaction ratio of the Co film and polysilicon film 120 may be 1:3 to 1:4. For example, the reaction ratio may be 1:3.49.

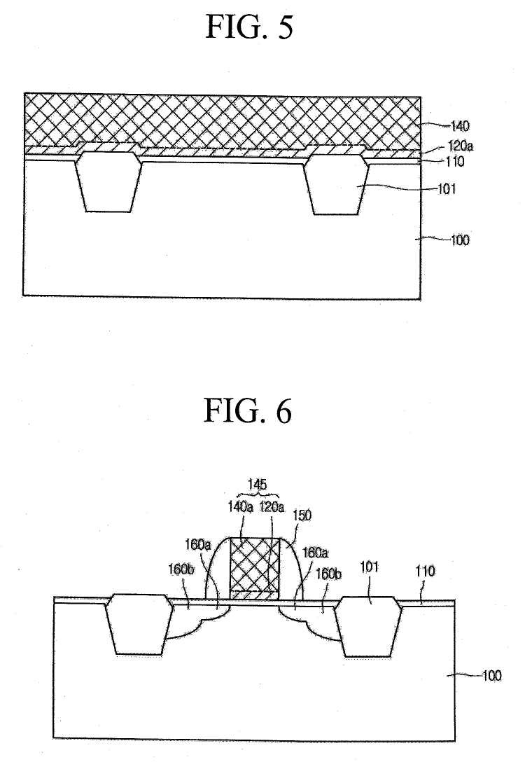

As shown in example FIG. 5, the semiconductor substrate 100 over which the polysilicon film 120 and metal film 130 are formed may be rapidly annealed using a rapid thermal process (RTP) apparatus. The RTP causes the polysilicon film 120 to react with the metal film, thereby forming a silicidation film 140 which is partially silicided. The rapid annealing process may include two steps: a primary annealing process, at a temperature of 400° C to 600° C. for about 40 to 80 seconds, and a secondary annealing process at a temperature of 600° C. to 1000° C. for about 10 to 50 seconds. The polysilicon film 120 is not silicided by a thickness of 10 Å to 50 Å from an interface with the gate oxynitride film 110 and forms a polysilicon area 120a. The work function may be properly controlled in a state where an n type or p type impurity is implanted into the polysilicon area 120a. Therefore, the silicidation film 140 over a top of the polysilicon area 120a reduces resistance of the gate. The polysilicon area 120a serves to control the work function.

As shown in example FIG. 6, the silicidation film 140 with the polysilicon area 120a under its bottom may be patterned to form a gate electrode 145. The gate electrode 145 may include the patterned silicidation film 140a and the patterned polysilicon 120a. A low-concentration ion implantation area 160a may be formed in the semiconductor substrate 100 using the gate electrode 145 as a mask. Thereafter, gate dielectric film spacers 150 covering both sides of the gate electrode 145 may be formed. A high-concentration ion implantation area 160b may be formed in the semiconductor substrate of the both sides of the gate electrode 145 and the dielectric film spacers 150 using the gate dielectric film spacers 150 and gate electrode 145 as a mask.

The semiconductor device and the method for fabricating the same according to embodiments form a gate pattern that is partially silicided to enable control of the work function diversely using the non-silicided polysilicon area. Also, the semiconductor device and the method for fabricating the same according to embodiments may be applied to transistors having a gate pattern whose work functions are different. The resistance of the gate electrode and junction can be reduced, making it possible to improve device characteristics.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate having at least one active area;
a gate dielectric film over an active area of the semiconductor substrate; and
a gate electrode over the gate dielectric film, the gate electrode formed of a silicidation film over a polysilicon area.

2. The apparatus of claim 1, wherein the polysilicon area has a thickness of 10 Å to 50 Å.

3. The apparatus of claim 1, wherein the polysilicon area is implanted with one of a p type and an n type impurity to control a work function.

4. The apparatus of claim 1, wherein the gate dielectric film is an oxynitride film.

5. The apparatus of claim 1, wherein the gate dielectric film is an oxide film.

6. A method comprising:
forming a gate dielectric film over a semiconductor substrate; and then
forming a polysilicon film over the gate dielectric film; and then
forming a metal film over the polysilicon film; and then
forming a silicidation film by reacting the metal film with a portion of the polysilicon film.

7. The method of claim 6, wherein the forming of the gate dielectric film includes:
forming an oxide film over the semiconductor substrate; and
forming the gate dielectric film made of an oxynitride film by performing an nitride plasma treatment on the oxide film.

8. The method of claim 7, wherein the gate oxide film is deposited over the semiconductor substrate under an oxygen atmosphere.

9. The method of claim 8, wherein the gate oxide film is deposited over the semiconductor substrate at a temperature of 700° C. to 900° C.

10. The method of claim 9, wherein the gate oxide film is deposited using a furnace thermal process.

11. The method of claim 6, wherein the gate oxide film is formed with a thickness of between 10 Å to 100 Å.

12. The method of claim 6, wherein the metal film includes at least one selected from a group consisting of Ni, Co, Ti, Ta, W and Pt.

13. The method of claim 6, wherein the polysilicon film is formed with a thickness of 500 Å to 2000 Å, and the metal film is formed with a thickness of 100 Å to 2000 Å.

14. The method of claim 6, wherein the forming of the silicidation film includes:
performing a primary rapid annealing process being annealed at a temperature of 400 to 600° C. for 40 to 80 seconds; and
performing a secondary rapid annealing process being annealed at a temperature of 600 to 1000° C. for 10 to 50 seconds.

15. The method of claim 6, wherein when forming the silicidation film, the polysilicon film which is not silicided remains a polysilicon region.

16. The method of claim 15, wherein the polysilicon region extends upward, between 10 Å to 50 Å, from an interface with the gate dielectric film.

17. The method of claim 6, including:
before forming the metal film, implanting one of an n type impurity and p type impurity into the polysilicon film.

18. The method of claim 6, wherein the metal film is an Ni film, and the reaction ratio of the Ni film and polysilicon film is between 1:1.7 and 1:2.7.

19. The method of claim 6, wherein the metal film is a Co film, and the reaction ratio of the Co film and polysilicon film is between 1:3 and 1:4.

20. The method of claim 6, wherein the polysilicon film is formed by a low-power chemical vapor deposition, at a temperature of about 500° C. to 550° C., and at a pressure of about 0.1 to 3 torr.
